(19) United States
(12) Patent Application Publication
(10) Pub. No.: US 2025/0079334 A1
(43) Pub. Date: Mar. 6, 2025

(54) REINFORCEMENT STRUCTURES FOR MULTI-DIE SEMICONDUCTOR PACKAGES AND METHODS OF FORMING THE SAME

(71) Applicant: Taiwan Semiconductor Manufacturing Company Limited, Hsinchu (TW)

(72) Inventors: Yu Chen Lee, Hsinchu City (TW); Chin-Hua Wang, New Taipei City (TW); Chun-Wei Chen, Taoyuan City (TW); Shin-Puu Jeng, Po-Shan Village (TW)

(21) Appl. No.: 18/457,523

(22) Filed: Aug. 29, 2023

(51) Int. Cl. H01L 23/00; H01L 21/56; H01L 23/29; H01L 23/31; H01L 25/00; H01L 25/065

(52) U.S. Cl. CPC H01L 23/562; H01L 21/56; H01L 23/293; H01L 23/3157; H01L 24/16; H01L 24/32; H01L 24/73; H01L 24/92; H01L 25/0655; H01L 25/50; H01L 2224/16227; H01L 2224/32225; H01L 2224/73204; H01L 2224/92125

(57) ABSTRACT

A semiconductor package may include a package substrate, a first semiconductor die electrically and mechanically coupled to the package substrate, a second semiconductor die electrically and mechanically coupled to the package substrate, and a reinforcement structure mechanically coupled to at least a first vertical surface of the first semiconductor die and a second vertical surface of the second semiconductor die, such that the reinforcement structure surrounds less than an entirety of the first semiconductor die and the second semiconductor die. The semiconductor package may include an underfill material formed between a top surface of the package substrate and bottom surfaces of the first semiconductor die and the second semiconductor die. The reinforcement structure may include a polymer material located in a space between the first semiconductor die and the second semiconductor die. The polymer material may be a polymer matrix composite having a greater modulus than the underfill material.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens, hundreds, or thousands of integrated circuits may be manufactured on a single semiconductor wafer, and individual dies on the wafer may be singulated by sawing between the integrated circuits along scribe lines. The individual dies may be packaged separately, in multi-chip modules, for example, or in other types of packaging.

As semiconductor packages have become more complex, package sizes have tended to become larger to accommodate greater numbers of integrated circuits and/or dies per package. These larger and more complex semiconductor packages have led to additional challenges in making effective and reliable electrical interconnections within the semiconductor package. Other challenges includes mechanical issues related to coefficient of thermal expansion (CTE) mismatch between package components leading to warpage, cracking, delamination, etc.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is vertical cross-sectional exploded view of components of a semiconductor package during a package assembly and surface mounting process.

FIG. 1B is a vertical cross-sectional view illustrating an assembled semiconductor package mounted onto a surface of a support substrate.

FIG. 2A is a top view of a semiconductor package including an external reinforcement structure.

FIG. 2B is a vertical cross-sectional view of the semiconductor package of FIG. 2A.

FIG. 2C is a vertical cross-sectional view of an enlarged portion of the semiconductor package of FIG. 2B.

FIG. 3A is a top view of a further semiconductor package, according to various embodiments.

FIG. 3B is a vertical cross-sectional view of the semiconductor package of FIG. 3A, according to various embodiments.

FIG. 4A is a top view of a further semiconductor package, according to various embodiments.

FIG. 4B is a top view of a further semiconductor package, according to various embodiments.

FIG. 4C is a top view of a further semiconductor package, according to various embodiments.

FIG. 5A is a top view of a further semiconductor package, according to various embodiments.

FIG. 5B is a vertical cross-sectional view of a portion of the semiconductor package of FIG. 5A, according to various embodiments.

FIG. 5C is a vertical cross-sectional view of a portion of an alternative semiconductor package similar to that of FIG. 5A, according to various embodiments.

FIG. 6A is a top view of a further semiconductor package, according to various embodiments.

FIG. 6B is a top view of a further semiconductor package, according to various embodiments.

FIG. 7 is flowchart illustrating operations of a method of forming a semiconductor package, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Generally, in a semiconductor package, one or more semiconductor integrated circuit (IC) dies may be mounted onto a common substrate, which may also be referred to as a “package substrate.” In some embodiments, electrical connections to the semiconductor package may be made by mounting the package substrate onto a support substrate containing electrical interconnects, such as a printed circuit board (PCB). A semiconductor die or multi-die chip may be attached to a package substrate using a mass reflow process to melt solder portions that may then re-solidify to form metallurgical bonds between respective electrical bonding structures on the semiconductor die (or multi-die chip) and the package substrate. A semiconductor package may further include various reinforcement structures (also referred to as wadding structures) to protect semiconductor IC dies and to reduce or eliminate mechanical damage that may otherwise arise due to thermal expansion stresses/strains that may be caused by differences in coefficients of thermal expansion (CTE) of the various components of a semiconductor package.

Mechanical issues may include mechanical stress/strain, warpage, delamination, etc. In this regard, during the assembly and operation of semiconductor devices, mechanical stress may be exerted on the package due to factors such as thermal expansion and contraction, vibrations, and external forces. Excessive mechanical stress may lead to failure of wire bonds, solder joints, or the package itself. To mitigate against this issue, proper package design, choice of materials with suitable mechanical properties, and the use of reinforcement structures (e.g., wadding structures) may be used. Warpage refers to the bending or distortion of the semiconductor package. Warpage may occur due to a mismatch in CTE between different materials used in the package assembly. Excessive warpage may cause poor electrical connections, stress concentration, and reliability issues. Proper material selection, thermal management, and package design techniques may help minimize warpage.

Delamination refers to the separation of different layers or interfaces within the semiconductor package. Delamination may be caused by factors such as moisture absorption, thermal cycling, and mechanical stress. Delamination may lead to a decrease in electrical performance, loss of mechanical strength, and increased vulnerability to environmental factors. Effective sealing techniques, moisture barrier materials, and proper manufacturing processes may help to prevent delamination.

Various embodiment semiconductor packages are disclosed herein, which may be advantageous by providing a reinforcement structure (e.g., wadding structures) formed in a central portion of the semiconductor package that provides mechanical support to, but surrounds less than an entirety of (i.e., does not surround), the semiconductor dies attached to a package substrate. The reinforcement structure may thus strengthen the semiconductor package without overly constraining relative motion (e.g., caused by thermal expansion) of the various components of the semiconductor package. As such, in contrast to related semiconductor packages that may be more constrained, various embodiment semiconductor dies disclosed herein may be configured to allow a greater degree of thermal expansion. The greater degree of thermal expansion may act to reduce thermal stresses/strains that may otherwise lead to cracking, deformation, and delamination in comparative semiconductor packages.

An embodiment semiconductor package may include a package substrate, a first semiconductor die electrically and mechanically coupled to the package substrate, a second semiconductor die electrically and mechanically coupled to the package substrate, and a reinforcement structure mechanically coupled to at least a first vertical surface of the first semiconductor die and a second vertical surface of the second semiconductor die, such that the reinforcement structure surrounds less than the entirety of the first semiconductor die and less than the entirety of the second semiconductor die (i.e., does not surround the first semiconductor die and/or does not surround the second semiconductor die). The semiconductor package may further include an underfill material formed between a top surface of the package substrate and bottom surfaces of the first semiconductor die and the second semiconductor die. The reinforcement structure may include a polymer material located in a space between the first semiconductor die and the second semiconductor die. The polymer material may be a polymer matrix composite having a greater modulus than the underfill material.

A further embodiment semiconductor package may include a package substrate, a first semiconductor die electrically and mechanically coupled to the package substrate, a second semiconductor die electrically and mechanically coupled to the package substrate, and a reinforcement structure formed in a vertical space between the first semiconductor die and the second semiconductor die. The reinforcement structure may have a first thickness that is less than or equal a second thickness of the first semiconductor die and the second semiconductor die, and the reinforcement structure may have a first width that is less than or equal to a second width of the first semiconductor die and the second semiconductor die. The semiconductor package may further include an underfill material formed between a top surface of the package substrate and bottom surfaces of the first semiconductor die and the second semiconductor die, and the reinforcement structure may have a greater modulus than the underfill material.

An embodiment method of forming a semiconductor package may include attaching a first semiconductor die to a package substrate such that the first semiconductor die is electrically and mechanically coupled to the package substrate, attaching a second semiconductor die to the package substrate such that the second semiconductor die is electrically and mechanically coupled to the package substrate, and forming a reinforcement structure mechanically coupled to at least a first vertical surface of the first semiconductor die and a second vertical surface of the second semiconductor die, such that the reinforcement structure surrounds less than the entirety of the first semiconductor die and less than the entirety of the second semiconductor die (i.e., does not surround the first semiconductor die and/or does not surround the second semiconductor die). The method may further include forming an underfill material between a top surface of the package substrate and bottom surfaces of the first semiconductor die and the second semiconductor die such that the underfill material has a modulus that is less than that of the reinforcement structure.

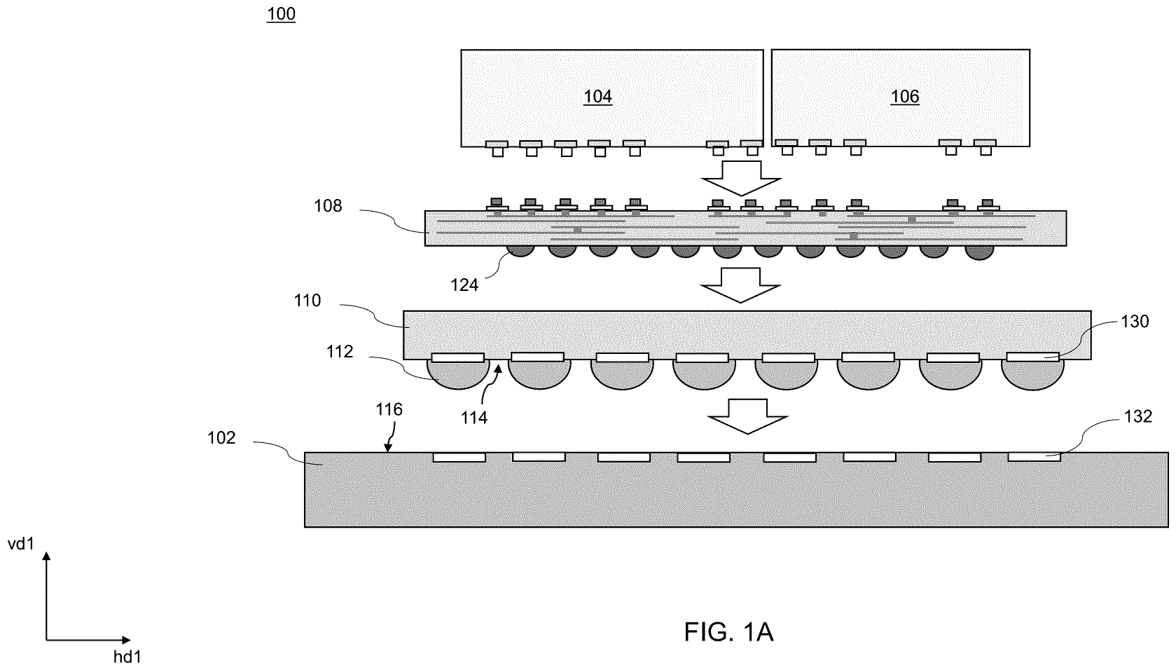

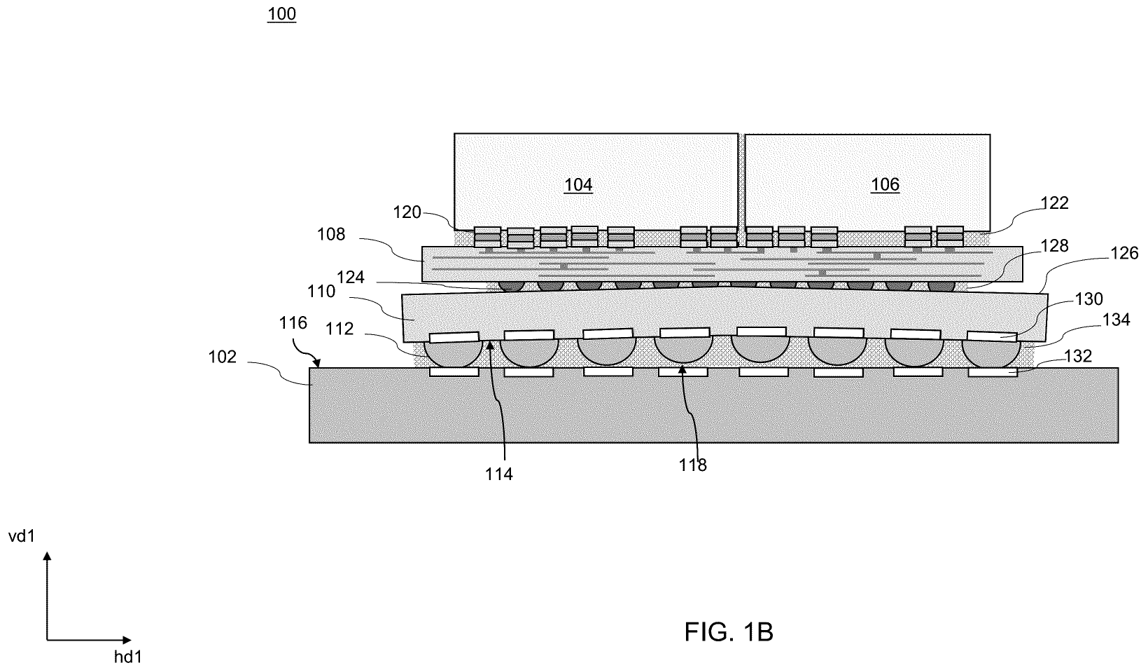

FIG. 1A is vertical cross-sectional exploded view of components of a semiconductor package 100 during a package assembly and surface mounting process. FIG. 1B is a vertical cross-sectional view illustrating the assembled semiconductor package 100 mounted onto the surface of a support substrate 102, such as a printed circuit board (PCB). The semiconductor package 100 is merely an example type of semiconductor package, although it will be understood that a similar assembly and mounting process may be utilized for other types of semiconductor packages.

Referring to FIGS. 1A and 1B, the semiconductor package may include integrated circuit (IC) semiconductor devices, such as first semiconductor dies 104 and second semiconductor dies 106. During the package assembly process, the first semiconductor die 104 and the second semiconductor die 106 may be mounted on an interposer 108 to form an semiconductor module. The interposer 108 having the first semiconductor die 104 and the second semiconductor die 106 mounted thereon may be mounted onto a package substrate 110 to form a semiconductor package 100 using a plurality of metal bumps 124. The semiconductor package 100 may then be mounted to a support substrate 102, such as a printed circuit board (PCB), by mounting the package substrate 110 to the support substrate 102 using an array of solder balls 112 on the lower surface 114 of the package substrate 110.

A parameter that may ensure proper interconnection between the package substrate 110 and the support substrate 102 is the degree of co-planarity between the surfaces of the solder balls 112 that may be brought into contact with the mounting surface (i.e., the upper surface 116 of the support substrate 102 in FIG. 1A). A low degree of co-planarity between the solder balls 112 may result in instances of solder cold joints (i.e., insufficient melting of the solder material, resulting in a poor bond that is susceptible to cracking and separation) and/or solder bridging issues (i.e., solder material from one solder ball 112 contacting material from a neighboring solder ball 112, resulting in an unintended connection (i.e., electrical short)) during the reflow process.

Deformation of the package substrate 110, such as stress-induced warping of the package substrate 110, may be a contributor to low co-planarity of the solder balls 112 during surface mounting of the package substrate 110 onto a support substrate 102. FIG. 1B illustrates a package substrate 110 that includes a warpage deformation. The warpage deformation of the package substrate 110 may result in variations of the distance between the lower surface 114 of the package substrate 110 and the upper surface 116 support substrate 102. Such deformation of the package substrate 110 may increase the risk of defective solder connections with the underlying support substrate 102. As shown in FIG. 1B, for example, a deformation of the package substrate 110 may cause at least some of the solder joints between the package substrate 110 and the support substrate 102 to fail completely, as indicated by the arrow 118 in FIG. 1B. In the exemplary embodiment shown in FIG. 1B, the deformation of the package substrate 110 may have a bow-shape or cup-shape such that a separation between the lower surface 114 of the package substrate 110 and the upper surface 116 of the support substrate 102 may be smallest at the periphery of the package substrate 110 and may increase towards the center of the package substrate 110.

Deformation of the package substrate 110 is not an uncommon occurrence, particularly in the case of semiconductor packages used in high-performance computing applications. These high-performance semiconductor packages 100 tend to be relatively large and may include a number of semiconductor dies (e.g., 104, 106) mounted to the package substrate 110, which may increase a likelihood that the package substrate 110 may be subject to warping or other deformations. Such deformations may present challenges to effective solder mounting of these types of package substrates 110 onto a support substrate 102.

In various embodiments, the first semiconductor dies 104 may be three-dimensional devices, such as three-dimensional integrated circuits (3DICs), system-on-chip (SoC), or system on integrated chips (SoIC) devices. A three-dimensional semiconductor die 104 may be formed by placing chips over chips on a semiconductor wafer level. These three-dimensional devices may provide improved integration density and other advantages, such as faster speeds and higher bandwidths, due to a decreased length of interconnects between the stacked chips. In some embodiments, a first three-dimensional semiconductor die 104 may also be referred to as a “first die stack.”

The second semiconductor die(s) 106 may be different from the first semiconductor die(s) 104 in terms of their structure, design and/or functionality. The one or more second semiconductor dies 106 may be three-dimensional semiconductor dies, which may also be referred to as “second die stacks.” In some embodiments, the one or more second semiconductor dies 106 may include a memory device, such as a high bandwidth memory (HBM) device. In the example shown in FIGS. 1A and 1B, the semiconductor package 100 may include a SOC die stack 104 and an HBM die stack 106, although it will be understood that the semiconductor package 100 may include greater or fewer numbers of semiconductor dies.

Referring again to FIG. 1B, the first semiconductor dies 104 and second semiconductor dies 106 may be mounted on an interposer 108. In some embodiments, the interposer 108 may be an organic interposer including a polymer dielectric material (e.g., a polyimide material) having a plurality of metal interconnect structures extending therethrough. In other embodiments, the interposer 108 may be a semiconductor interposer, such as a silicon interposer, having a plurality of interconnect structures (e.g., through-silicon vias) extending therethrough. Other suitable configurations for the interposer 108 are within the contemplated scope of the disclosure. The interposer 108 may include a plurality of conductive bonding pads on upper and lower surfaces of the interposer and a plurality of conductive interconnects extending through the interposer 108 between the upper and lower bonding pads of the interposer 108. The conductive interconnects may distribute and route electrical signals between the first semiconductor dies 104, the second semiconductor dies 106, and the underlying package substrate 110. Thus, the interposer 108 may also be referred to as a redistribution layer (RDL). In other embodiments, the interposer 108 may be omitted and semiconductor dies (104, 106) may be directly mounted to the package substrate 110.

A plurality of metal bumps 120, such as microbumps, may electrically connect conductive bonding pads on the bottom surfaces of the first semiconductor dies 104 and second semiconductor dies 106 to the conductive bonding pads on the upper surface of the interposer 108 (or to bonding pads (not shown) on the package substrate 110 in other embodiments). In one non-limiting embodiment, metal bumps 120 in the form of microbumps may include a plurality of first metal stacks, such as a plurality of Cu—Ni—Cu stacks, located on the bottom surfaces of the first semiconductor dies 104 and second semiconductor dies 106, and a plurality of second metal stacks (e.g., Cu—Ni—Cu stacks) located on the upper surface of the interposer 108. A solder material, such as tin (Sn), may be located between respective first and second metal stacks to electrically connect the first semiconductor dies 104 and the second semiconductor dies 106 to the interposer 108. Other suitable materials for the metal bumps 120 are within the contemplated scope of disclosure.

After the first semiconductor dies 104 and second semiconductor dies 106 are mounted to the interposer 108, a first underfill material portion 122 may optionally be provided in the spaces surrounding the metal bumps 120 and between the bottom surfaces of the first semiconductor dies 104, the second semiconductor dies 106, and the upper surface of the interposer 108 as shown in FIG. 1B. The first underfill material portion 122 may also be provided in the spaces laterally separating adjacent first semiconductor dies 104 and second semiconductor dies 106 of the semiconductor package 100. In various embodiments, the first underfill material portion 122 may include an epoxy-based material, which may include a composite of resin and filler materials.

Referring again to FIG. 1B, the interposer 108 may be mounted on the package substrate 110 that may provide mechanical support for the interposer 108 and the first semiconductor dies 104 and second semiconductor dies 106 that are mounted on the interposer 108. The package substrate 110 may include a suitable material, such as an organic material (e.g., a polymer and/or thermoplastic material), a semiconductor material (e.g., a semiconductor wafer, such as a silicon wafer), a ceramic material, a glass material, combinations thereof, etc. Other suitable substrate materials are within the contemplated scope of present disclosure. In various embodiments, the package substrate 110 may include a plurality of conductive bonding pads (not shown) in an upper surface 126 of the package substrate 110. A plurality of metal bumps 124, such as C4 solder bumps, may electrically connect conductive bonding pads (not shown) on the bottom surface of the interposer 108 to the conductive bonding pads on the upper surface 126 of the package substrate 110. In various embodiments, the metal bumps 124 may include a suitable solder material, such as tin (Sn), although other suitable solder materials are within the contemplated scope of disclosure.

A second underfill material portion 128 may be provided in the spaces surrounding the metal bumps 124 and between the bottom surface of the interposer 108 and the upper surface 126 of the package substrate 110 as illustrated, for example, in FIG. 1B. In various embodiments, the second underfill material portion 128 may include an epoxy-based material, which may include a composite of resin and filler materials. In some embodiments, a lid or cover (not shown in FIGS. 1A and 1B) may be mounted to the package substrate 110 and may provide an enclosure around the upper and side surfaces of the first semiconductor dies 104 and second semiconductor dies 106.

As described above, the package substrate 110 may be mounted to the support substrate 102, such as a printed circuit board (PCB). Other suitable support substrates 102 are within the contemplated scope of disclosure. The package substrate 110 may include a plurality of conductive bonding pads 130 in a lower surface 114 of the package substrate 110. A plurality of conductive interconnects (not shown) may extend through the package substrate 110 between conductive bonding pads on the upper surface 126 and lower surface 114 of the package substrate 110. The plurality of solder balls (or bump structures) 112 may electrically connect the conductive bonding pads 130 on the lower surface 114 of the package substrate 110 to a plurality of conductive bonding pads 132 on the upper surface 116 of the support substrate 102.

The conductive bonding pads 130 of the package substrate 110 and conductive bonding pads 132 of the support substrate 102 may be formed of a suitable conductive material, such as copper. Other suitable conductive materials are within the contemplated scope of disclosure. The plurality of solder balls 112 on the lower surface 114 of the package substrate 110 may form an array of solder balls 112, such as a ball grid array (BGA) that may include an array pattern that corresponds to an array pattern of the conductive bonding pads 132 on the upper surface 116 of the support substrate 102. In one non-limiting example, the array of solder balls 112 may include a grid pattern and may have a pitch (i.e., distance between the center of each solder ball 112 and the center of each adjacent solder ball 112). In an example embodiment, the pitch may be between about 0.8 and 1.0 mm, although larger and smaller pitches may be used. The solder balls 112 may include any suitable solder material, such as tin, lead, silver, indium, zinc, nickel, bismuth, antimony, cobalt, copper, germanium, alloys thereof, combinations thereof, or the like. Other suitable materials for the solder balls 112 are within the contemplated scope of disclosure.

In some embodiments, the lower surface 114 of the package substrate 110 may include a coating of solder resist (SR) material (not shown), which may also be referred to as a “solder mask”. A SR material coating may provide a protective coating for the package substrate 110 and any underlying circuit patterns formed on or within the package substrate 110. An SR material coating may also inhibit solder material from adhering to the lower surface 114 of the package substrate 110 during a reflow process. In embodiments in which the lower surface 114 of the package substrate 110 includes an SR coating, the SR material coating may include a plurality of openings through which the conductive bonding pads 130 may be exposed.

In various embodiments, each of the conductive bonding pads 130 in different regions of the package substrate 110 may have the same size and shape. In the embodiment shown in FIGS. 1A and 1B, the surfaces of the conductive bonding pads 130 may be substantially co-planar with the lower surface 114 of the package substrate 110, which in some embodiments may include a solder resist (SR) coating. Alternatively, the surfaces of the conductive bonding pads 130 may be recessed relative to the lower surface 114 of the package substrate 110. In some embodiments, the surfaces of the conductive bonding pads 130 may be raised relative to the lower surface 114 of the package substrate 110.

Referring again to FIGS. 1A and 1B, solder balls 112 may be provided over the respective conductive bonding pads 130. In one non-limiting example, the conductive bonding pads 130 may have a width dimension that is between about 500 μm and about 550 μm (e.g., ˜530 μm), and the solder balls 112 may have an outer diameter that may be between about 600 μm and about 650 μm (e.g., ˜630 μm), although greater and lesser dimensions for the solder balls 112 and/or the conductive bonding pads 130 are within the contemplated scope of disclosure.

A first solder reflow process may include subjecting the package substrate 110 to an elevated temperature (e.g., at least about 250° C.) to melt the solder balls 112 and cause the solder balls 112 to adhere to the conductive bonding pads 130. Following the first reflow process, the package substrate 110 may be cooled causing the solder balls 112 to re-solidify. Following the first solder reflow process, the solder balls 112 may adhere to the conductive bonding pads 130. Each solder ball 112 may extend from the lower surface 114 of the package substrate 110 by a vertical height that may be less than the outer diameter of the solder ball 112 prior to the first reflow process. For example, where the outer diameter of the solder ball 112 is between about 600 μm and about 650 μm (e.g., ˜630 μm), the vertical height of the solder ball 112 following the first reflow process may be between about 500 μm and about 550 μm (e.g., ˜520 μm).

In various embodiments, the process of mounting the package substrate 110 onto the support substrate 102 as shown in FIG. 1B, may include aligning the package substrate 110 over the support substrate 102, such that the solder balls 112 contacting the conductive bonding pads 130 of the package substrate 110 may be located over corresponding bonding pads (e.g., conductive bonding pads 132) on the support substrate 102. A second solder reflow process may then be performed. The second solder reflow process may include subjecting the package substrate 110 to an elevated temperature (e.g., at least about 250° C.) to thereby melt the solder balls 112 and cause the solder balls 112 to adhere to the corresponding conductive bonding pads 132 on the support substrate 102. Surface tension may cause the semi-liquid solder to maintain the package substrate 110 in alignment with the support substrate 102 while the solder material cools and solidifies. Upon solidification of the solder balls 112, the package substrate 110 may sit above the upper surface 116 of the support substrate 102 by a stand-off height that may be between about 0.4 mm to about 0.5 mm, although greater or lesser stand-of heights are within the contemplated scope of disclosure.

Following the mounting of the package substrate 110 to the support substrate 102, a third underfill material portion 134 may be provided in the spaces surrounding the solder balls 112 and between the lower surface 114 of the package substrate 110 and the upper surface 116 of the support substrate 102, as is shown in FIG. 1B. In various embodiments, the third underfill material portion 134 may include an epoxy-based material, which may include a composite of resin and filler materials.

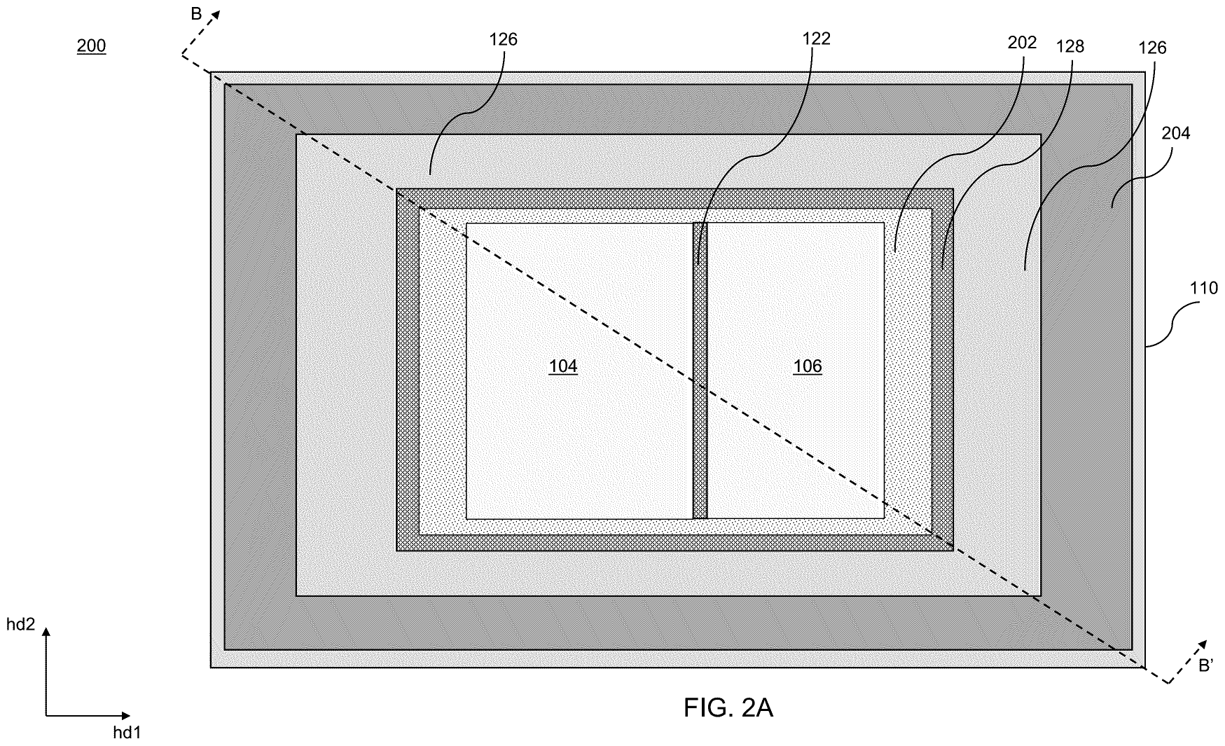

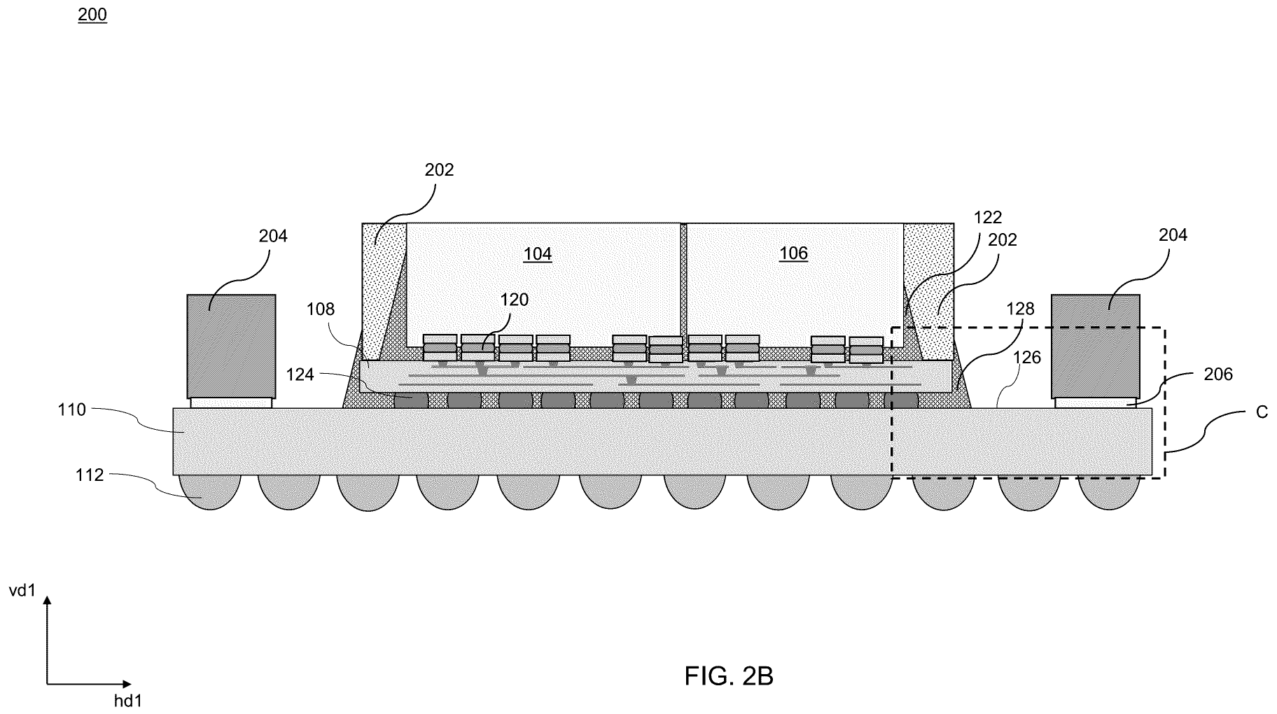

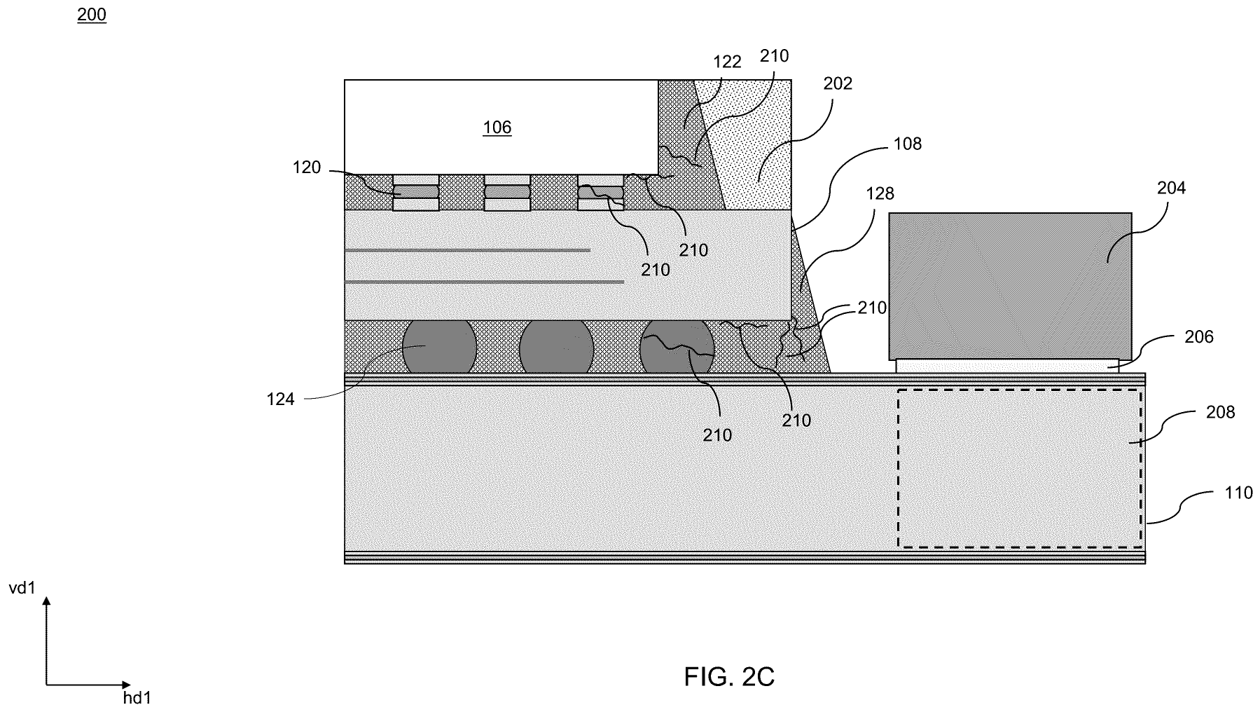

FIG. 2A is a top view of a semiconductor package 200 including an external reinforcement structure 204, which may be provided to reduce or eliminate the warpage distortion of the package substrate 110 shown in FIG. 1B. The dashed line labeled B-B′ indicates the cross-sectional view of the semiconductor package 200 shown in FIG. 2B, as described in greater detail, below. The semiconductor package 200 may be similar to the semiconductor package 100 of FIGS. 1A and 1B. In this regard, the semiconductor package 200 may include a first semiconductor die 104 and a second semiconductor die 106 mounted to an interposer 108 (e.g., see FIG. 2B). The interposer 108 may be mounted to a package substrate 110, as described above with reference to FIGS. 1A and 1B. The semiconductor package 200 may include a first underfill material portion 122 provided in the spaces laterally separating the adjacent first semiconductor die 104 and second semiconductor die 106 of the semiconductor package 200. The semiconductor package 200 may also include a second underfill material portion 128 which may be provided in the spaces surrounding the metal bumps 124 and between the bottom surface of the interposer 108 and the upper surface 126 of the package substrate 110 as illustrated, for example, in FIG. 2B.

The semiconductor package 200 may further include an epoxy molding compound (EMC) that may be applied to gaps formed between the interposer 108, the first semiconductor die 104, and the second semiconductor die 106, to thereby form a multi-die EMC frame 202. The EMC material may include an epoxy-containing compound that may be hardened (i.e., cured) to provide a dielectric material portion having sufficient stiffness and mechanical strength. The EMC material may include epoxy resin, hardener, silica (as a filler material), and other additives. The EMC material may be provided in a liquid form or in a solid form depending on the viscosity and flowability.

Liquid EMC may provide better handling, good flowability, fewer voids, better fill, and fewer flow marks. Solid EMC may provide less cure shrinkage, better stand-off, and less die drift. A high filler content (such as 85% in weight) within an EMC material may shorten the time in mold, lower the mold shrinkage, and reduce the mold warpage. A uniform filler size distribution in the EMC material may reduce flow marks and may enhance flowability. The curing temperature of the EMC material may be in a range from 125° C. to 150° C. The multi-die EMC frame 202 may be cured at a curing temperature to form an EMC matrix that laterally encloses each of the first semiconductor die 104 and the second semiconductor die 106. Excess portions of the multi-die EMC frame 202 may be removed from above the horizontal plane including the top surfaces of the semiconductor dies (104, 106) by a planarization process, such as CMP.

FIG. 2B is a cross-sectional view of the semiconductor package 200 of FIG. 2A. The external reinforcement structure 204 may be attached to the package substrate 110 with an adhesive 206 and may be formed of a metal, an insulator, a semiconductor, a ceramic, etc. For example, in one embodiment, the external reinforcement structure 204 may include copper at an atomic percentage greater than 80%, such as greater than 90%, greater than 95%, greater than 99%, etc. In other embodiments greater or lesser percentages may be used. As shown in FIG. 2A, the external reinforcement structure 204 may be configured as a ring located around a periphery of the package substrate 110. As such, the external reinforcement structure 204 may form a single structure. Alternatively, the external reinforcement structure 204 may include several disconnected portions (not shown). Further, the external reinforcement structure 204 need not be located near the periphery of the package substrate 110. Rather, the external reinforcement structure 204 may be located on the package substrate 110 in any region that may be subject to mechanical distortions such as warping.

The external reinforcement structure 204 may provide increased mechanical support to the package substrate 110 to thereby reduce or eliminate mechanical distortions such as the warping of the package substrate 110 described above and illustrated, for example, in FIG. 1B. The external reinforcement structure 204 may therefore be chosen to have a mechanical strength (e.g., modulus) that is greater than that of the package substrate 110. As described above, the package substrate 110 may include an organic material (e.g., a polymer and/or thermoplastic material), a semiconductor material (e.g., a semiconductor wafer, such as a silicon wafer), a ceramic material, a glass material, combinations thereof, etc. As such, the choice of material for the external reinforcement structure 204 may be chosen based on the mechanical properties of the package substrate 110. As shown in FIG. 2B, for example, the presence of the external reinforcement structure 204 may reduce or eliminate the warpage distortion of the package substrate 110 shown in FIG. 1B. However, the presence of the external reinforcement structure 204 may give rise to other mechanical issues as described in greater detail with reference to FIG. 2C, below.

FIG. 2C is a cross-sectional view of an enlarged portion of the semiconductor package of FIG. 2B. The region shown in FIG. 2C is illustrated in the dashed rectangle labeled C in FIG. 2B. For certain material compositions, there may be a mismatch in thermal expansion coefficients of components of the semiconductor package 200 relative to a thermal expansion coefficient of the external reinforcement structure 204. As such, thermal expansion stresses may develop during thermal cycling. Such thermal stresses may lead to mechanical degradation of the semiconductor package 200. For example, as shown in FIG. 2C, cracks 210 may develop in the first underfill material portion 122, in the second underfill material portion 128, at interfaces, within the metal bumps 124, etc. Further, one or both of the first underfill material portion 122 and the second underfill material portion 128 may become delaminated (not shown) from the package substrate 110 and/or from the interposer 108.

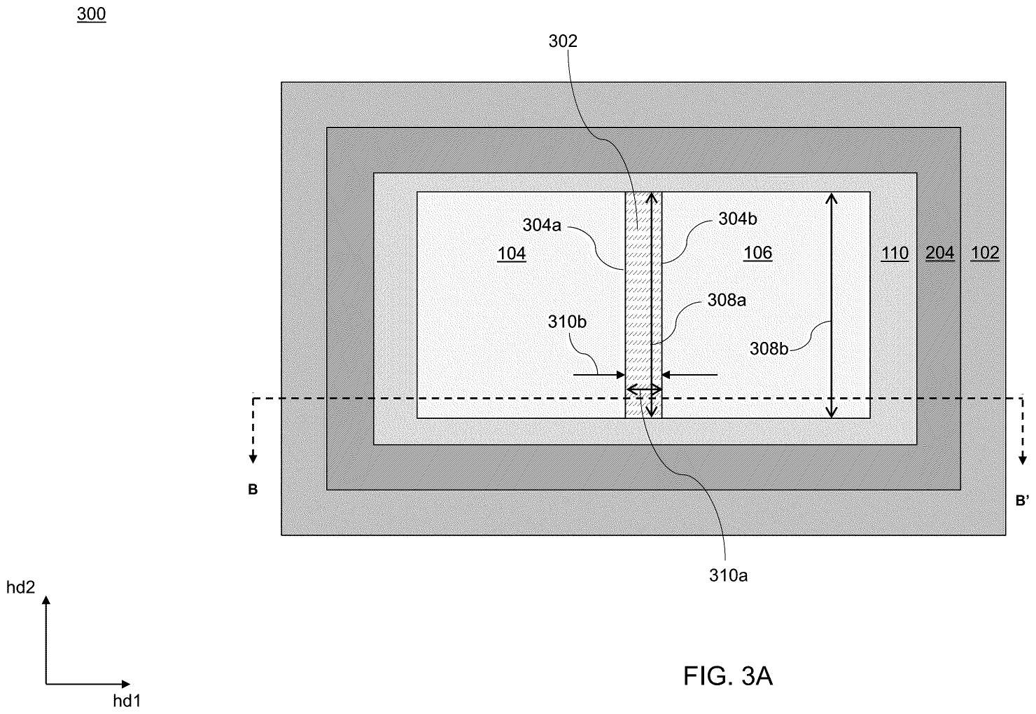

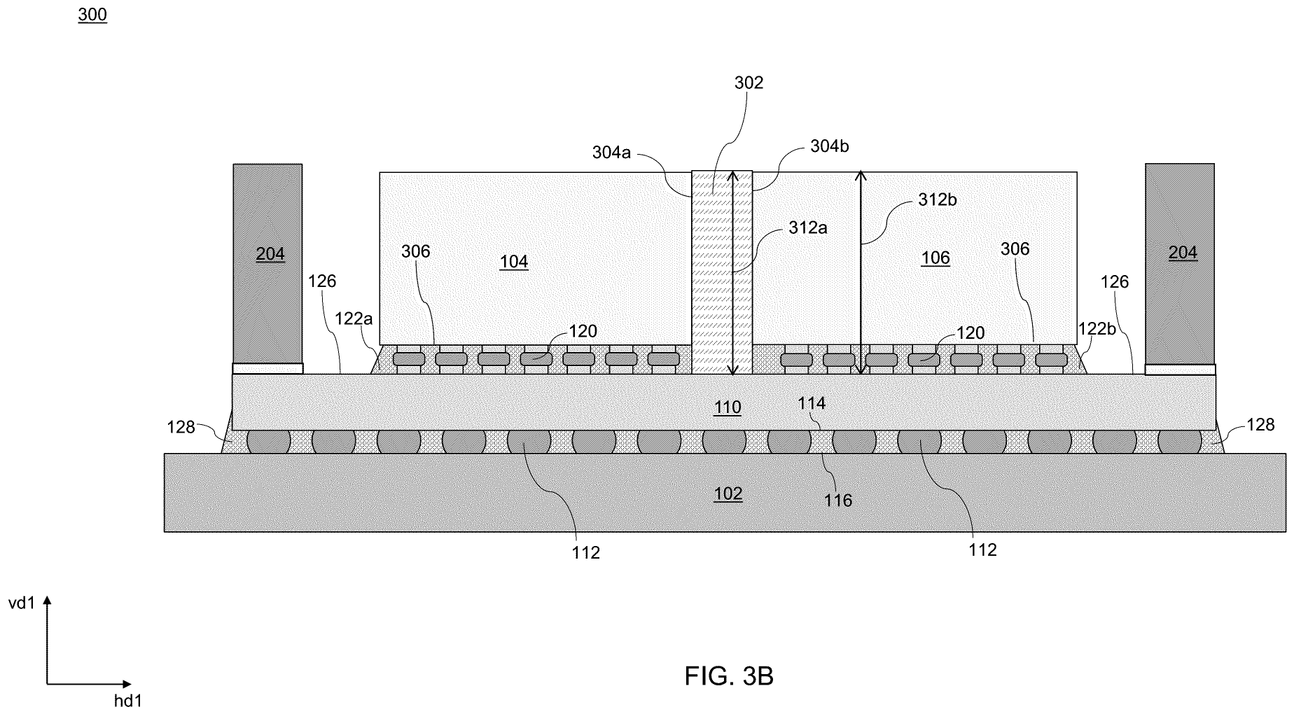

In various disclosed embodiments, one or more additional reinforcement structures (not shown) may be provided to mitigate against the thermal stresses developed between components of the semiconductor package 200 and the external reinforcement structure 204. For example, in some embodiments, a package reinforcement structure (not shown) may be formed within the package substrate 110 (e.g., within region 208 in FIG. 2C). Alternatively, other methods of forming semiconductor packages may mitigate the above-described issues related to mechanical deformation/degradation that may arise due to thermally-induced stresses/strains, as described in greater detail with reference to FIGS. 3A to 6B, below.

FIG. 3A is a top view of a further semiconductor package 300, and FIG. 3B is a vertical cross-sectional view of the semiconductor package 300 of FIG. 3A, according to various embodiments. The plane defining the vertical cross-sectional view of FIG. 3B is indicated by the cross section B-B′ shown in FIG. 3A. As shown in FIGS. 3A and 3B, the semiconductor package 300 may include a package substrate 110, a first semiconductor die 104 electrically and mechanically coupled to the package substrate 110, a second semiconductor die 106 electrically and mechanically coupled to the package substrate 110, and a reinforcement structure 302 mechanically coupled to at least a first vertical surface 304a of the first semiconductor die 104 and a second vertical surface 304b of the second semiconductor die 106. The package substrate 110 may be further electrically and mechanically coupled to a support substrate 102, such as a PCB. In some embodiments, an external reinforcement structure 204 may also be included, as described in greater detail with reference to FIGS. 2A to 2C. In contrast to the embodiment semiconductor package 100 of FIGS. 1A and 1B and the embodiment semiconductor package 200 of FIGS. 2A to 2C, however, the semiconductor package 300 of FIGS. 3A and 3B may omit the interposer 108 in certain embodiments.

As shown in FIGS. 3A and 3B, the reinforcement structure 302 may be formed only in a central portion of the semiconductor package 300. In this way, the reinforcement structure 302 surrounds less than the entirety of the first semiconductor die 104 and less than the entirety of the second semiconductor die 106 (i.e., does not surround the first semiconductor die 104 and/or does not surround the second semiconductor die 106). As such, the reinforcement structure 302 is distinguished from the multi-die EMC frame 202 of the semiconductor package 200 of FIGS. 2A to 2C, which surrounds the first semiconductor die 104 and the second semiconductor die 106. The reinforcement structure 302 may thus strengthen the semiconductor package 300 without overly constraining relative motion (e.g., thermal expansion) of the various components (e.g., the first semiconductor die 104 and the second semiconductor die 106) of the semiconductor package 300. As such, in contrast to the semiconductor package 200 of FIGS. 2A to 2C, the first semiconductor die 104 and the second semiconductor die 106 may be configured allow for an additional degree of thermal expansion. Such a configuration may act to reduce thermal stresses/strains that may otherwise lead to cracking, deformation, and delamination as shown in the comparative semiconductor package 200 of FIGS. 2A to 2C. In this regard, the semiconductor package 300 of FIGS. 3A and 3B may provide advantages over the related semiconductor package 200 of FIGS. 2A to 2C for certain applications.

The semiconductor package 300 of FIGS. 3A and 3B may further include a first underfill material (122a, 122b) formed between an upper surface 126 of the package substrate 110 and bottom surfaces 306 of the first semiconductor die 104 and the second semiconductor die 106. The semiconductor package 300 may further include a second underfill material 128 formed between a upper surface 116 of the support substrate 102 and a lower surface 114 of the package substrate 110. The reinforcement structure 302 may be formed of a polymer material having a greater modulus than the first underfill material (122a, 122b). In other embodiments, the reinforcement structure 302 may have a modulus that is less than that of the first underfill material (122a, 122b). For example, the reinforcement structure 302 may be a polymer matrix composite material that may have a modulus (and other properties) that may be tuned by adjusting the composition of the polymer matrix composite (e.g., changing a composition of the polymer material and/or a density and composition of a filler material).

As shown in FIG. 3B, the reinforcement structure 302 may be formed in a space between the first semiconductor die 104 and the second semiconductor die 106 such that the reinforcement structure 302 makes contact with the upper surface 126 of the package substrate 110 as well as with the first vertical surface 304a of the first semiconductor die 104 and the second vertical surface 304b of the second semiconductor die 106. As such, the reinforcement structure 302 may effectively divide the first underfill material (122a, 122b) into a first portion 122a and a second portion 122b. For example, the reinforcement structure 302 may be formed after attaching the first semiconductor die 104 and the second semiconductor die 106 to the package substrate 110 but before forming the first underfill material (122a, 122b). In other embodiments (not shown), the reinforcement structure 302 may be formed after the first underfill material (122a, 122b) is formed. As such, the reinforcement structure 302 may be formed over the first underfill material (122a, 122b). In such embodiments, the first portion 122a and the second portion 122b may form a continuous layer of underfill material (not shown).

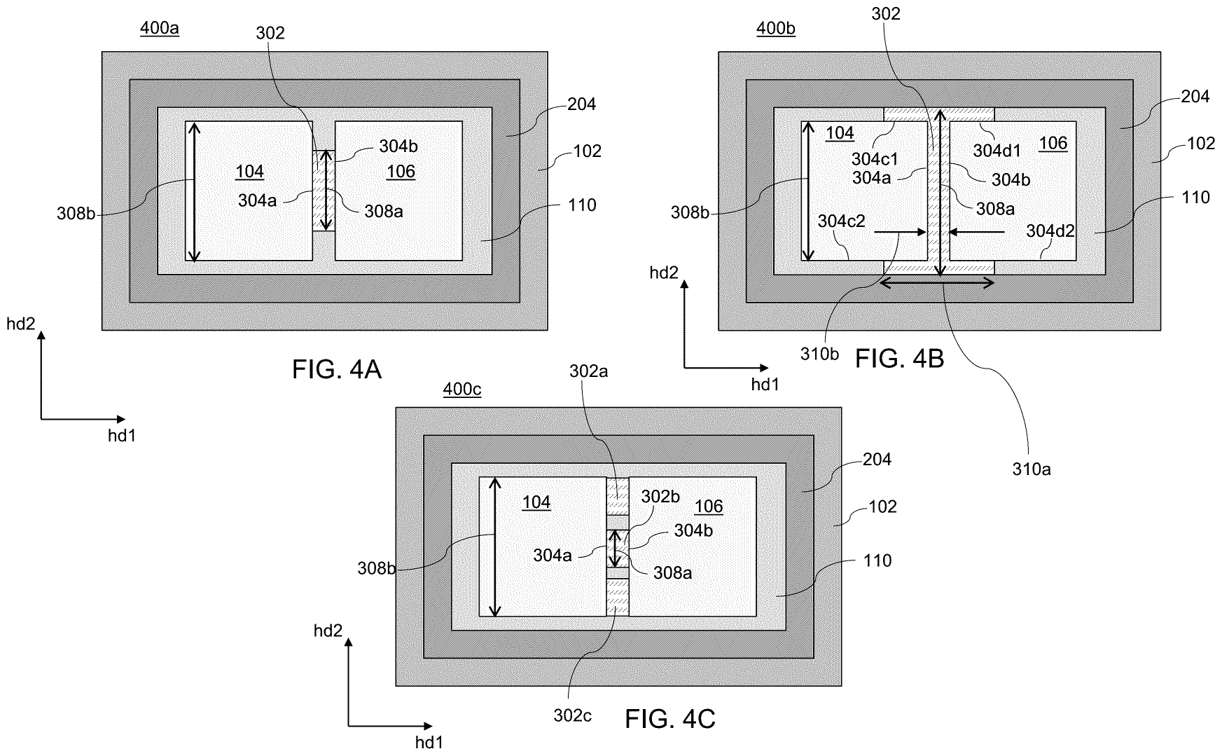

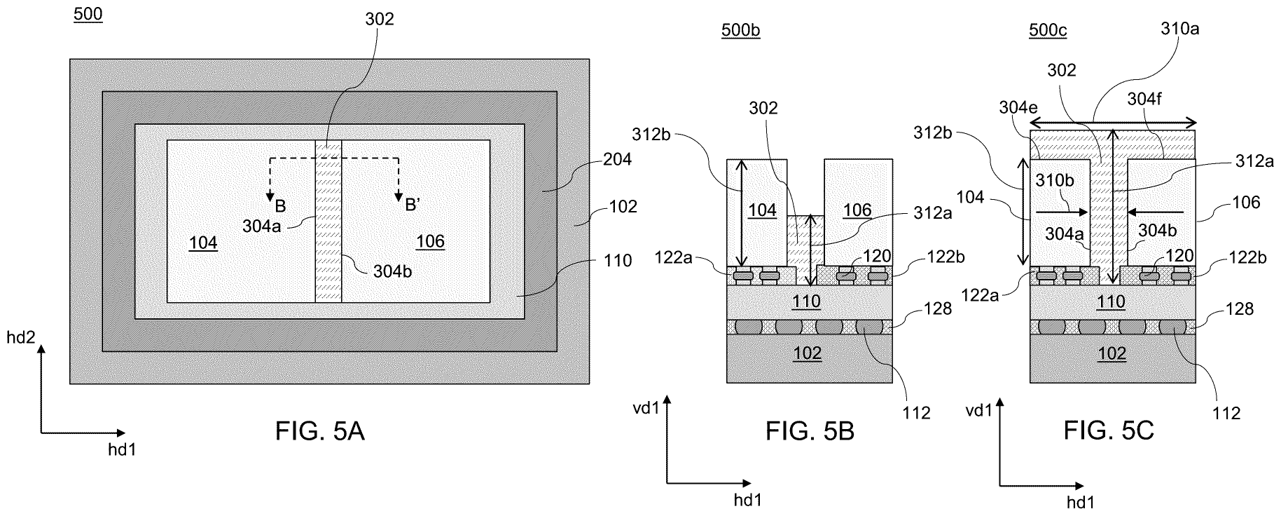

As shown in FIG. 3A, in some embodiments, the reinforcement structure 302 may have a first length 308a that may be substantially equal to a respective second length 308b of the first semiconductor die 104 and the second semiconductor die 106. Similarly, in some embodiments, the reinforcement structure 302 may have a first width 310a that may be substantially equal to a second width 310b corresponding to a size of a space between the first semiconductor die 104 and the second semiconductor die 106. As shown in FIG. 3B, in some embodiments, the reinforcement structure 302 may also have a first thickness 312a (measured relative to the upper surface 126 of the package substrate 110) that may be substantially equal to that of a second thickness 312b (measured relative to the upper surface 126 of the package substrate 110) of the first semiconductor die 104 and the second semiconductor die 106. In various other embodiments, the reinforcement structure 302 may have various values of the first length 308a, first width 310a, and the first thickness 312a relative to the respective second length 308b, second width 310b, and second thickness 312b of the first semiconductor die 104 and the second semiconductor die 106, as described in greater detail with reference to FIGS. 4A to 5C, below. For example, in some embodiments, the reinforcement structure 302 may have a first length 308a that may be substantially less to a respective second length 308b of the first semiconductor die 104 and the second semiconductor die 106. In other embodiments, the reinforcement structure 302 may have first length 308a that may be greater than a respective second length 308b of the first semiconductor die 104 and the second semiconductor die 106.

FIGS. 4A to 4C are top views of respective semiconductor packages (400a, 400b, 400c) having various configurations of the reinforcement structure 302, according to various embodiments. As shown in FIG. 4A, for example, a first length 308a of the reinforcement structure 302 may be less than a second length 308b of the first semiconductor die 104 and the second semiconductor die 106. As such, in the semiconductor package 400a of FIG. 4A, the reinforcement structure 302 may formed so as to be in contact only with a portion of a first vertical surface 304a of the first semiconductor die 104 and a portion of a second vertical surface 304b of the second semiconductor die 106.

In other embodiments, the reinforcement structure 302 may have other configurations in which the reinforcement structure 302 may be in contact with various other surfaces of the first semiconductor die 104 and the second semiconductor die 106. For example, as shown in FIG. 4B, the first length 308a of the reinforcement structure 302 may be greater than the second length 308b of the first semiconductor die 104 and the second semiconductor die 106. Further, the first width 310a of the reinforcement structure 302 may be greater than second width 310b corresponding to a size of a space between the first semiconductor die 104 and the second semiconductor die 106. As such, the reinforcement structure 302 may be formed in contact with at least two side surfaces (304c, 304d) of the first semiconductor die 104 and the second semiconductor die 106. In this regard, in addition to contacting the first vertical surface 304a of the first semiconductor die 104 and the second vertical surface 304b of the second semiconductor die 106, the reinforcement structure 302 may also be formed to be contacting third vertical surfaces 304cl of the first semiconductor die 104 and fourth vertical surface 340c2 of the first semiconductor die 104 as well as a fifth vertical surfaces 304d1 of the second semiconductor die 106 and a sixth vertical surface 304d2 of the second semiconductor die 106.

In further embodiments, as shown in the semiconductor package 400c of FIG. 4C, the reinforcement structure 302 may be formed as two or more separated portions (302a, 302b, 302c) that each make contact with the first vertical surface 304a of the first semiconductor die 104 and the second vertical surface 304b of the second semiconductor die 106. In the example embodiment semiconductor package 400c of FIG. 4C, the reinforcement structure 302 may include a first portion 302a, a second portion 302b, and a third portion 302c. In other embodiments, the reinforcement structure 302 may have more or fewer separated portions that may each make contact with the first vertical surface 304a of the first semiconductor die 104 and the second vertical surface 304b of the second semiconductor die 106. In still further embodiments, the various separated portions of the reinforcement structure 302 may be formed to make contact with various other surfaces (e.g., third vertical surfaces 304c1, fourth vertical surfaces 304c2, fifth vertical surface 34d1, sixth vertical surface 304d2) of the first semiconductor die 104 and the second semiconductor die 106.

The reinforcement structures 302 in the example semiconductor packages (400a, 400b, 400c) of FIGS. 4A to 4C may provide various degrees of mechanical constraint to the first semiconductor die 104 and the second semiconductor die 106. For example, reinforcement structure 302 of FIG. 4A, which contacts only the first vertical surface 304a of the first semiconductor die 104 and the second vertical surface 304b of the second semiconductor die 106 may constrain the first semiconductor die 104 and the second semiconductor die 106 to a lesser degree than that of the reinforcement structure 302 of the semiconductor package 400b of FIG. 4B. In this regard, the reinforcement structure 302 of the semiconductor package 400b of FIG. 4B, which is formed in contact with six surfaces (304a, 304b, 304c1, 304c2, 304d1, 304d2), may provide a greater degree of mechanical constraint between the first semiconductor die 104 and the second semiconductor die 106 than that of the reinforcement structure 302 of the semiconductor package 400a of FIG. 4A, which is formed in contact with only two surfaces (302a, 302b).

In other embodiments, the reinforcement structure (302a, 302b, 302c) of the semiconductor package 400c of FIG. 4C may provide a greater or lesser mechanical constraint to the first semiconductor die 104 and the second semiconductor die 106 as respective reinforcement structures 302 of the semiconductor package 400a and the semiconductor package 400b. For example, in some embodiments, the reinforcement structure 302 of the semiconductor package 400c may provide a greater mechanical constraint than that of the semiconductor package 400a while providing a lesser mechanical constraint than that of the semiconductor package 400b. In this regard, the degree to which the first semiconductor die 104 and the second semiconductor die 106 are mechanically constrained may be chosen for a given application by corresponding design of the reinforcement structure 302.

FIG. 5A is a top view of a further semiconductor package 500, and FIG. 5B is a vertical cross-sectional view of a portion 500a of the semiconductor package 500 of FIG. 5A, according to various embodiments. FIG. 5C is a vertical cross-sectional view of a portion 500c of an alternative semiconductor package similar to that of FIG. 5A, according to various embodiments. The plane defining the vertical cross-sectional view of FIGS. 5B and 5C is indicated by the cross section B-B′ shown in FIG. 5A. The semiconductor package 500 may be similar to the semiconductor package 300 of FIGS. 3A and 3B. In this regard, the semiconductor package 500 may include a package substrate 110, a first semiconductor die 104 electrically and mechanically coupled to the package substrate 110, a second semiconductor die 106 electrically and mechanically coupled to the package substrate 110, and a reinforcement structure 302 mechanically coupled to at least a first vertical surface 304a of the first semiconductor die 104 and a second vertical surface 304b of the second semiconductor die 106. The semiconductor package 500 may further include an external reinforcement structure 204 and the package substrate may be attached to a support substrate 102.

As with the embodiment semiconductor packages 300, 400a, 400b, 400c, described with reference to FIGS. 3A to 4C, above, the reinforcement structure 302 of the semiconductor package 500 may be configured to surround less than the entirety of the first semiconductor die 104 and less than the entirety of the second semiconductor die 106 (i.e., does not surround the first semiconductor die 104 and/or does not surround the second semiconductor die 106). As such, in contrast to the EMC die frame 202 of FIG. 2B, the reinforcement structure 302 may mechanically constrain the first semiconductor die 104 and the second semiconductor die 106 to a lesser extent, which may be advantageous in certain applications. For example, as described above, the reduced mechanical constraint of the first semiconductor die 104 and the second semiconductor die 106 may allow for a greater relative thermal expansion which may act to reduce thermal expansion induced stresses and strains.

As shown in FIG. 5B, in contrast to semiconductor package 300 of FIG. 3B, the reinforcement structure 302 may have a first thickness 312a that may be less than a second thickness 312b of the first semiconductor die 104 and the second semiconductor die 106. As such, the reinforcement structure 302 of the semiconductor package 500 may constrain the first semiconductor die 104 and the second semiconductor die 106 to a lesser degree than that of the corresponding reinforcement structure 302 of the semiconductor package 300 shown in FIG. 3B. In this regard, the first thickness 312a may be chosen such that the reinforcement structure 302 provides a pre-determined degree of mechanical constraint of the first semiconductor die 104 and the second semiconductor die 106.

In further embodiments, as shown in FIG. 5C, the reinforcement structure 302 may have a first thickness 312a that may be greater than a second thickness 312b of the first semiconductor die 104 and the second semiconductor die 106. Further, as with the embodiment semiconductor package 400b of FIG. 4B, the first width 310a of the reinforcement structure 302 may be greater than the second width 310b corresponding to a size of a space between the first semiconductor die 104 and the second semiconductor die 106. As such, while surrounding less than the entirety of the first semiconductor die 104 and less than the entirety of the second semiconductor die 106 (i.e., the reinforcement structure 302 does not surround the first semiconductor die 104 and/or does not surround the second semiconductor die 106), the reinforcement structure 302 may be configured to be in contact with at least a first top surface 304e of the first semiconductor die 104 and a second top surface 304f of the second semiconductor die 106 and thereby to mechanically support the first semiconductor die 104 and the second semiconductor die 106.

In this regard, in addition to contacting the first vertical surface 304a of the first semiconductor die 104 and the second vertical surface 304b of the second semiconductor die 106, the reinforcement structure 302 may also be formed to be contacting a first top surface 304e of the first semiconductor die 104 as well as a second top surface 304f of the second semiconductor die 106. By contacting four surfaces (304a, 304b, 304e, 304f) the reinforcement structure 302 of the embodiment portion 500c of the semiconductor package of FIG. 5C may provide a relatively greater mechanical constraint to the first semiconductor die 104 and the second semiconductor die 106 than that provided by the respective reinforcement structure 302 of the semiconductor package 500/500b of FIGS. 5A and 5B.

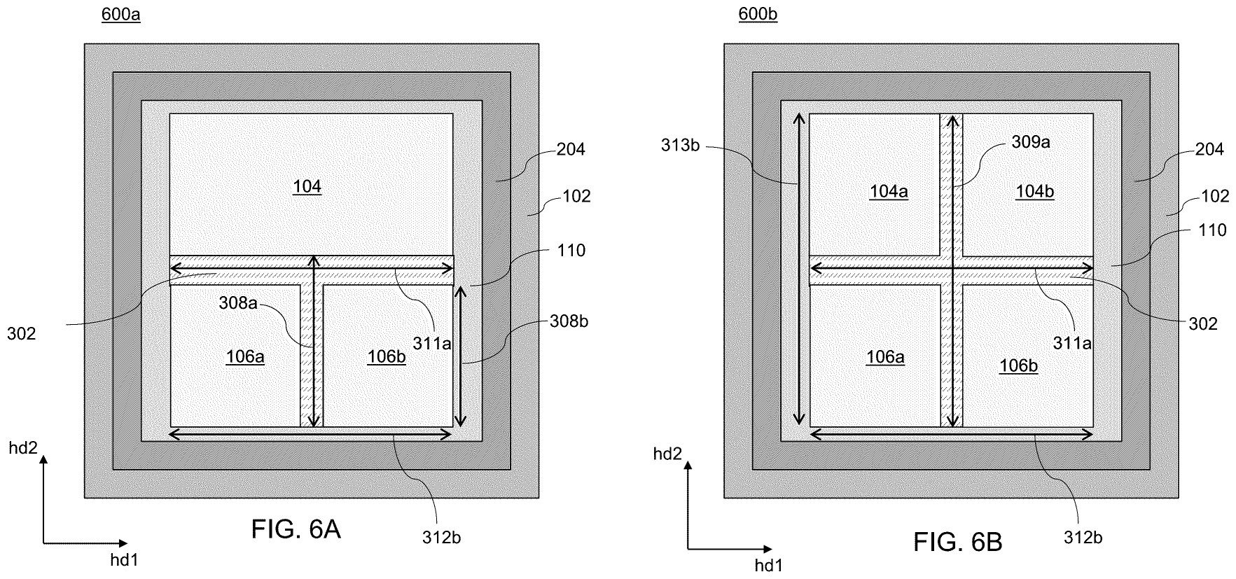

FIGS. 6A and 6B are top views of further semiconductor packages 600a and 600b, respectively, according to various embodiments. The semiconductor package 600a may include a first semiconductor die 104 and two second semiconductor dies (106a, 106b) each electrically and mechanically coupled to a package substrate 110. Similarly, the semiconductor package 600b may include two first semiconductor dies (104a, 104b) and two second semiconductor dies (106a, 106b) each electrically and mechanically coupled to a package substrate 110. Still further semiconductor packages may include a first semiconductor die 104, a second semiconductor die 106, and a third semiconductor die (not shown). Each of the first semiconductor package 600a and the second semiconductor package 600b may further include a respective reinforcement structure 302 that may be coupled to the two or more semiconductor dies (104, 104a, 104b, 106a, 106b). Each of the first semiconductor package 600a and the second semiconductor package 600b may further include an external reinforcement structure 204 and the respective package substrates 110 may be electrically and mechanically coupled to a support substrate 102.

As described above with reference to FIGS. 3A to 5C, the reinforcement structures 302 of first semiconductor package 600a and the second semiconductor package 600b may be configured to constrain, but to surround less than an entirety of, the various semiconductor dies (104, 104a, 104b, 106a, 106b). A length 308a, length 309a, width 311a, and thickness (not shown) of the reinforcement structure 302 may be varied in the first semiconductor package 600a and the second semiconductor package 600b, as described above with respect to other embodiments. In this regard, each reinforcement structure 302 may have a first length 308a that may be greater than, less than, or equal to a second length 308b corresponding to a length of one or more semiconductor dies (104, 106). For example, in the semiconductor package 600a of FIG. 6A, the first length 308a may be greater than the second length 308b corresponding to a length of the second semiconductor dies (106a, 106b). In contrast, in the semiconductor package 600b of FIG. 6B, the first length 309a may be substantially equal to the second length 309b corresponding to a combined length of the first semiconductor dies (104a, 104b) and the second semiconductor dies (106a, 106b).

Similarly, each reinforcement structure 302 in the first semiconductor package 600a and the second semiconductor package 600b may have a first width 311a that may be greater than, less than, or equal to a second width 311b corresponding to a width of one or more semiconductor dies (104, 106). For example, in the semiconductor package 600a of FIG. 6A and the semiconductor package 600b of FIG. 6B, the first width 311a may be substantially equal to the second width 311b corresponding to a width of two of the second semiconductor dies (106a, 106b). Various other embodiments may include reinforcement structures 302 having corresponding lengths 308a, 309a, widths 311a, and thicknesses (not shown in FIGS. 6A and 6B). Each of the length 308a, length 309a, width 311a, and thickness of the corresponding reinforcement structures 302 may be varied independently to provide mechanical reinforcement to corresponding semiconductor packages (300, 400a, 400b, 400c, 600a, 600b) that may be optimized for specific applications. The reinforcement structure 302 may thus strengthen the semiconductor package (300, 400a, 400b, 400c, 500, 500c, 600a, 600b) without overly constraining relative motion (e.g., thermal expansion) of the various components of the semiconductor package (300, 400a, 400b, 400c, 500, 500c, 600a, 600b). As such, the first semiconductor die 104 and the second semiconductor die 106 may be configured allow an additional degree of thermal expansion that may act to reduce thermal stresses/strains that may otherwise lead to cracking, deformation, and delamination in other embodiments that may have increased constraints.

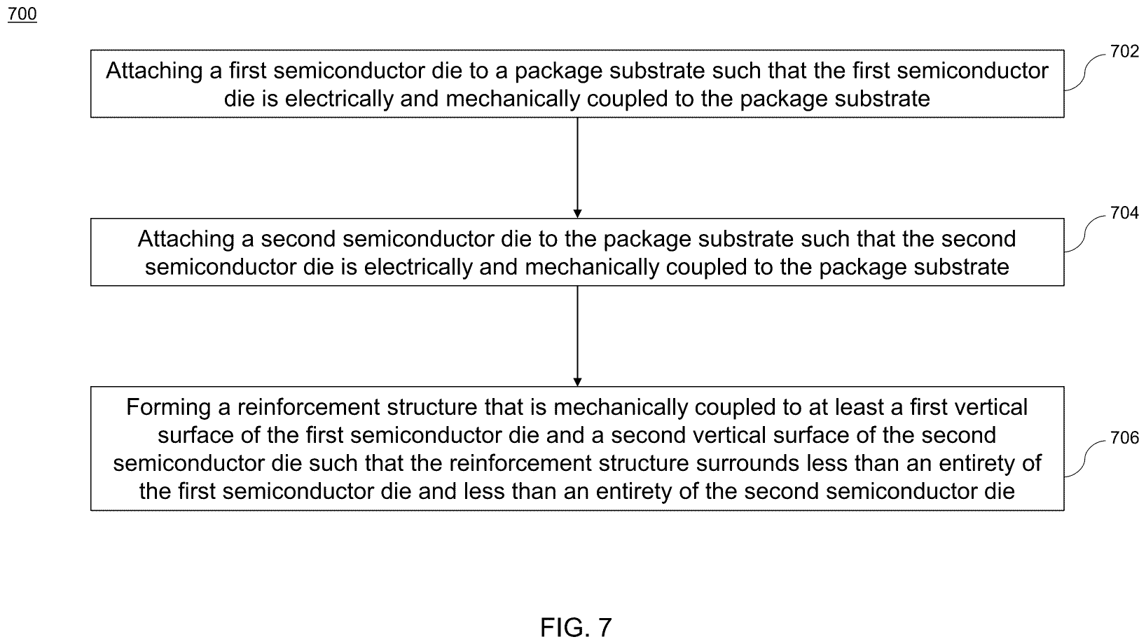

FIG. 7 is flowchart illustrating operations of a method 700 of forming a semiconductor package (300, 400a, 400b, 400c, 500, 500c, 600a, 600b), according to various embodiments. In operation 702, the method 700 may include attaching a first semiconductor die 104 to a package substrate 110 such that the first semiconductor die 104 is electrically and mechanically coupled to the package substrate 110. In operation 704, the method 700 may include attaching a second semiconductor die 106 to the package substrate 110 such that the second semiconductor die 106 is electrically and mechanically coupled to the package substrate 110. In operation 706, the method 700 may include forming a reinforcement structure 302 that is mechanically coupled to at least a first vertical surface 304a of the first semiconductor die 104 and a second vertical surface 304b of the second semiconductor die 106, such that the reinforcement structure 302 surrounds less than the entirety of the first semiconductor die 104 and less than the entirety of the second semiconductor die 106 (i.e., the reinforcement structure 302 does not surround the first semiconductor die 104 and/or does not surround the second semiconductor die 106).

The method 700 may further include forming an underfill material (122a, 122b) between an upper surface 126 of the package substrate 110 and bottom surfaces 306 of the first semiconductor die 104 and the second semiconductor die 106 such that the underfill material (122a, 122b) has a modulus that is less than that of the reinforcement structure 302. The method 700 may further include forming the reinforcement structure 302 according to operation 706. In an embodiment, forming the reinforcement structure 302 that is mechanically coupled to at least a first vertical surface 304a of the first semiconductor die 104 and a second vertical surface 304b of the second semiconductor die 106 such that the reinforcement structure 302 surrounds less than the entirety of the first semiconductor die 104 and less than the entirety of the second semiconductor die 106 according to operation 706. In some embodiments, the operation 706 of forming the reinforcement structure 302 may further include forming the reinforcement structure 302 to include two or more separated portions (302a, 302b, 302c) that each make contact with a first vertical surface 304a of the first semiconductor die 104 and a second vertical surface 304b of the second semiconductor die 106. The method 700 may further include attaching one or more additional semiconductor dies (104a, 104b, 106a, 106b) to the package substrate 110 such that one or more additional semiconductor dies (104a, 104b, 106a, 106b) are electrically and mechanically coupled to the package substrate 110. In this regard, forming the reinforcement structure 302 may further include forming the reinforcement structure 302 to be coupled to the one or more additional semiconductor dies (104a, 104b, 106a, 106b) but to surround less than an entirety of the one or more additional semiconductor dies (104a, 104b, 106a, 106b).

Referring to all drawings and according to various embodiments of the present disclosure, a semiconductor package (300, 400a, 400b, 400c, 500, 500c, 600a, 600b) is provided. The semiconductor package (300, 400a, 400b, 400c, 500, 500c, 600a, 600b) may include a package substrate 110, a first semiconductor die 104 electrically and mechanically coupled to the package substrate 110, a second semiconductor die 106 electrically and mechanically coupled to the package substrate 110, and a reinforcement structure 302 mechanically coupled to at least a first vertical surface 304a of the first semiconductor die 104 and a second vertical surface 304b of the second semiconductor die 106, such that the reinforcement structure 302 surrounds less than the entirety of the first semiconductor die 104 and the second semiconductor die 106 (i.e., the reinforcement structure 302 does not surround the first semiconductor die 104 and/or does not surround the second semiconductor die 106).

The semiconductor package (300, 400a, 400b, 400c, 500, 500c, 600a, 600b) may further include an underfill material (122a, 122b) formed between a upper surface 126 of the package substrate 110 and bottom surfaces 306 of the first semiconductor die 104 and the second semiconductor die 106. The reinforcement structure 302 may further include a polymer matrix composite material having a greater modulus than the underfill material (122a, 122b). In further embodiments, the reinforcement structure 302 may include a polymer material located in a space between the first semiconductor die 104 and the second semiconductor die 106. In certain embodiments, a first length (308a, 309a) of the reinforcement structure 302 is less than or equal to a second length (308b, 309b) of the first semiconductor die 104 and the second semiconductor die 106.

In other embodiments, a first length 308a of the reinforcement structure 302 may be greater than a second length 308b of the first semiconductor die 104 and the second semiconductor die 106 such that the reinforcement structure 302 is contacting at least two side surfaces (304c, 304d) of the first semiconductor die 104 and the second semiconductor die 106. Similarly, a first thickness 312a of the reinforcement structure 302 may be less than or equal to a second thickness 312b of the first semiconductor die 104 and the second semiconductor die 106. In other embodiments, a first thickness 312a of the reinforcement structure 302 may be greater than a second thickness 312b of the first semiconductor die 104 and the second semiconductor die 106 such that the reinforcement structure 302 may be contacting at least one upper surface 126 of the first semiconductor die 104 and the second semiconductor die 106.

In some embodiments, the reinforcement structure 302 may include two or more separated portions (302a, 302b, 302c) that may each make contact with the first vertical surface 304a of the first semiconductor die 104 and the second vertical surface 304b of the second semiconductor die 106. The semiconductor package (300, 400a, 400b, 400c, 500, 500c, 600a, 600b) may further include one or more additional semiconductor dies (104a, 104b, 106a, 106b) that are electrically and mechanically coupled to the package substrate 110. In such embodiments, the reinforcement structure 302 may be further coupled to the one or more additional semiconductor dies (104a, 104b, 106a, 106b) but may be configured to surround less than an entirety of the one or more additional semiconductor dies (104a, 104b, 106a, 106b) (i.e., the reinforcement structure 302 does not surround the first semiconductor die 104 and/or does not surround the second semiconductor die 106).

According to other embodiments of the present disclosure, a further semiconductor package (300, 400a, 400b, 400c, 500, 500c, 600a, 600b) is provided. The semiconductor package (300, 400a, 400b, 400c, 500, 500c, 600a, 600b) may include a package substrate 110, a first semiconductor die 104 electrically and mechanically coupled to the package substrate 110, a second semiconductor die 106 electrically and mechanically coupled to the package substrate 110, and a reinforcement structure 302 formed in a vertical space between the first semiconductor die 104 and the second semiconductor die 106. The reinforcement structure 302 may include a first thickness 312a that may be less than or equal a second thickness 312b of the first semiconductor die 104 and the second semiconductor die 106. Further, the reinforcement structure 302 may include a first width (310a, 311a) that may be less than or equal to a second width (310b, 311b) of the first semiconductor die 104 and the second semiconductor die 106.

The semiconductor package (300, 400a, 400b, 400c, 500, 500c, 600a, 600b) may further include an underfill material (122a, 122b) formed between a upper surface 126 of the package substrate 110 and bottom surfaces 306 of the first semiconductor die 104 and the second semiconductor die 106. The reinforcement structure 302 may further have a greater modulus than the underfill material (122a, 122b). In certain embodiments, the reinforcement structure 302 may further include a polymer matrix composite material.

In certain embodiments, the reinforcement structure 302 may be coupled only to a first vertical surface 304a of the first semiconductor die 104 and only to a second vertical surface 304b of the second semiconductor die 106. In other embodiments, the reinforcement structure 302 may include two or more separated portions (302a, 302b, 302c) that each make contact with the first vertical surface 304a of the first semiconductor die 104 and the second vertical surface 304b of the second semiconductor die 106. The semiconductor package (300, 400a, 400b, 400c, 500, 500c, 600a, 600b) may further include one or more additional semiconductor dies (104a, 104b, 106a, 106b) that are electrically and mechanically coupled to the package substrate 110. In such embodiments, the reinforcement structure 302 may be further coupled to the one or more additional semiconductor dies (104a, 104b, 106a, 106b) but may surround less than an entirety of the one or more additional semiconductor dies (104a, 104b, 106a, 106b).

The above-described embodiment semiconductor packages (300, 400a, 400b, 400c, 600a, 600b) may be advantageous by providing a reinforcement structure 302 formed in a central portion of the semiconductor package (300, 400a, 400b, 400c, 500, 500c, 600a, 600b) that provides mechanical support to, but surrounds less than an entirety of, semiconductor dies (104, 104a, 140b, 106, 106a, 106b) attached to a package substrate 110. The reinforcement structure 302 may thus strengthen the semiconductor package (300, 400a, 400b, 400c, 500, 500c, 600a, 600b) without overly constraining relative motion (e.g., caused by thermal expansion) of the various components of the semiconductor package (300, 400a, 400b, 400c, 500, 500c, 600a, 600b). As such, in contrast semiconductor packages 200 that may be more significantly constrained, the semiconductor dies (104, 106) of the semiconductor package (300, 400a, 400b, 400c, 500, 500c, 600a, 600b) may be configured to allow a greater degree of thermal expansion that may act to reduce thermal stresses/strains that may otherwise lead to cracking, deformation, and delamination in comparative semiconductor packages 200.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a package substrate;
a first semiconductor die electrically and mechanically coupled to the package substrate;
a second semiconductor die electrically and mechanically coupled to the package substrate; and
a reinforcement structure mechanically coupled to at least a first vertical surface of the first semiconductor die and a second vertical surface of the second semiconductor die,
wherein the reinforcement structure surrounds less than an entirety of the first semiconductor die and the second semiconductor die.

2. The semiconductor package of claim 1, further comprising an underfill material formed between a top surface of the package substrate and bottom surfaces of the first semiconductor die and the second semiconductor die.

3. The semiconductor package of claim 2, wherein the reinforcement structure comprises a polymer matrix composite material having a greater modulus than the underfill material.

4. The semiconductor package of claim 1, wherein the reinforcement structure comprises a polymer material located in a space between the first semiconductor die and the second semiconductor die.

5. The semiconductor package of claim 4, wherein a first length of the reinforcement structure is less than or equal to a second length of the first semiconductor die and the second semiconductor die.

6. The semiconductor package of claim 4, wherein a first length of the reinforcement structure is greater than a second length of the first semiconductor die and the second semiconductor die such that the reinforcement structure is contacting at least two side surfaces of the first semiconductor die and the second semiconductor die.

7. The semiconductor package of claim 4, wherein a first thickness of the reinforcement structure is less than or equal to a second thickness of the first semiconductor die and the second semiconductor die.

8. The semiconductor package of claim 4, wherein a first thickness of the reinforcement structure is greater than a second thickness of the first semiconductor die and the second semiconductor die such that the reinforcement structure is contacting at least one top surface of the first semiconductor die and the second semiconductor die.

9. The semiconductor package of claim 4, wherein the reinforcement structure comprises two or more separated portions that each make contact with the first vertical surface of the first semiconductor die and the second vertical surface of the second semiconductor die.

10. The semiconductor package of claim 4, further comprising one or more additional semiconductor dies that are electrically and mechanically coupled to the package substrate,
wherein the reinforcement structure is further coupled to the one or more additional semiconductor dies but surrounds less than an entirety of the one or more additional semiconductor dies.

11. A semiconductor package, comprising:
a package substrate;
a first semiconductor die electrically and mechanically coupled to the package substrate;
a second semiconductor die electrically and mechanically coupled to the package substrate; and
a reinforcement structure formed in a vertical space between the first semiconductor die and the second semiconductor die,
wherein the reinforcement structure comprises a first width that is less than or equal to a second width of the first semiconductor die and the second semiconductor die.

12. The semiconductor package of claim 11, further comprising an underfill material formed between a top surface of the package substrate and bottom surfaces of the first semiconductor die and the second semiconductor die,
wherein the reinforcement structure comprises a greater modulus than the underfill material.

13. The semiconductor package of claim 11, wherein the reinforcement structure further comprises a polymer matrix composite material.

14. The semiconductor package of claim 11, wherein the reinforcement structure is coupled only to a first vertical surface of the first semiconductor die and only to a second vertical surface of the second semiconductor die.

15. The semiconductor package of claim 14, wherein the reinforcement structure comprises two or more separated portions that each make contact with the first vertical surface of the first semiconductor die and the second vertical surface of the second semiconductor die.

16. The semiconductor package of claim 11, further comprising one or more additional semiconductor dies that are electrically and mechanically coupled to the package substrate,
wherein the reinforcement structure is further coupled to the one or more additional semiconductor dies but surrounds less than an entirety of the one or more additional semiconductor dies.

17. A method of forming a semiconductor package, comprising:
attaching a first semiconductor die to a package substrate such that the first semiconductor die is electrically and mechanically coupled to the package substrate;
attaching a second semiconductor die to the package substrate such that the second semiconductor die is electrically and mechanically coupled to the package substrate; and
forming a reinforcement structure mechanically coupled to at least a first vertical surface of the first semiconductor die and a second vertical surface of the second semiconductor die, such that the reinforcement structure surrounds less than an entirety of the first semiconductor die and the second semiconductor die.

18. The method of claim 17, further comprising forming an underfill material between a top surface of the package substrate and bottom surfaces of the first semiconductor die and the second semiconductor die such that the underfill material comprises a modulus that is less than that of the reinforcement structure.

19. The method of claim 17, wherein forming the reinforcement structure further comprises forming the reinforcement structure to comprise two or more separated portions that each make contact with the first vertical surface of the first semiconductor die and the second vertical surface of the second semiconductor die.

20. The method of claim 17, further comprising:
attaching one or more additional semiconductor dies to the package substrate such that one or more additional semiconductor dies are electrically and mechanically coupled to the package substrate; and
wherein forming the reinforcement structure further comprises forming the reinforcement structure to be coupled to the one or more additional semiconductor dies but to surround less than an entirety of the one or more additional semiconductor dies.
